(19) United States
(12) Patent Application Publication
(10) Pub. No.: US 2022/0390562 A1
(43) Pub. Date: Dec. 8, 2022

(54) ELECTRICAL AND PHOTONIC INTEGRATED CIRCUITS ARCHITECTURE

(71) Applicants: Guiyun Bai, Chandler, AZ (US); Sushrutha Gujjula, Chandler, AZ (US); Ronald L. Spreitzer, Phoenix, AZ (US); Naresh Satyan, Pasadena, CA (US); David Mathine, ALBUQUERQUE, NM (US); Sam Khalili, San Jose, CA (US); Sanjeev Gupta, Santa Rosa, CA (US); Eleanor Patricia Paras Rabadam, Folsom, CA (US); Ankur Agrawal, Chandler, AZ (US); Kenneth Brown, Mesa, AZ (US); Jonathan Doylend, Morgan Hill, CA (US); Daniel Grodensky, Haifa (IL); Israel Petronius, Haifa (IL)

(72) Inventors: Guiyun Bai, Chandler, AZ (US); Sushrutha Gujjula, Chandler, AZ (US); Ronald L. Spreitzer, Phoenix, AZ (US); Naresh Satyan, Pasadena, CA (US); David Mathine, ALBUQUERQUE, NM (US); Sam Khalili, San Jose, CA (US); Sanjeev Gupta, Santa Rosa, CA (US); Eleanor Patricia Paras Rabadam, Folsom, CA (US); Ankur Agrawal, Chandler, AZ (US); Kenneth Brown, Mesa, AZ (US); Jonathan Doylend, Morgan Hill, CA (US); Daniel Grodensky, Haifa (IL); Israel Petronius, Haifa (IL)

(21) Appl. No.: 17/557,290

(22) Filed: Dec. 21, 2021

Related U.S. Application Data
(60) Provisional application No. 63/196,095, filed on Jun. 2, 2021.

(51) Int. Cl. G01S 7/481; B81B 7/02; G01S 17/931

(52) U.S. Cl. CPC G01S 7/4811; B81B 7/02; G01S 17/931; B81B 2201/04

(57) ABSTRACT

Disclosed herein are microelectronics packages and methods for manufacturing the same. The microelectronics packages may include a photonic integrated circuit (PIC), an electrical integrated circuit (EIC), and an interconnect. The interconnect may connect the EIC to the PIC. The interconnect may include a plurality of paths between the EIC and the PIC and the individual paths of the plurality of paths are less than 100 micrometers long.

### PRIORITY CLAIM

The present application claims priority to U.S. Provisional Application No. 63/196,095, entitled “Technologies for Flip Chip Assembly,” filed on Jun. 2, 2021; the contents of which are hereby incorporated in their entirety.

### FIELD OF THE DISCLOSURE

The present subject matter relates to microelectronics package architectures. More specifically, the present disclosure relates to microelectronics package architectures for an electrical integrated circuit communication with a photonic integrated circuit.

### BACKGROUND

Silicon photonics is commonly used in various optical technology, including Light Detection and Ranging (LIDAR) systems. A LIDAR system includes many optical components such as a trans-impedance amplifier, laser drivers, optical switches, semiconductor optical amplifiers, radio frequency modulators, etc. A LIDAR system may include both electrical integrated circuits (EICs) as well as photonic integrated circuits (PICs). Communications and other signals may be shared between EICs and PICs as part of LIDAR systems.

### BRIEF DESCRIPTION OF THE FIGURES

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a side view of a simplified diagram of a component of a LIDAR system in accordance with at least one embodiment of this disclosure.

FIG. 2 illustrates a side view of a simplified diagram of a portion of a LIDAR in accordance with at least one embodiment of this disclosure.

FIG. 3 illustrates a side view of a chip-on-wafer silicon-to-silicon interconnect in accordance with at least one embodiment of this disclosure.

FIG. 4 illustrates a side view of a simplified diagram of a portion of a LIDAR system in accordance with at least one embodiment of this disclosure.

FIG. 5 illustrates a top-down view of a simplified diagram of a component of a LIDAR system in accordance with at least one embodiment of this disclosure.

FIG. 6 illustrates a side view of a simplified diagram of a LIDAR system in accordance with at least one embodiment of this disclosure.

FIG. 7 illustrates a side view of a simplified diagram of a portion of a LIDAR system in accordance with at least one embodiment of this disclosure.

FIG. 8 is a top view of a wafer and dies that may be included in a microelectronic assembly in accordance with at least one embodiment of this disclosure.

FIG. 9 is a cross-sectional side view of an integrated circuit device that may be included in a microelectronic assembly in accordance with at least one embodiment of this disclosure.

FIG. 10 is a cross-sectional side view of an integrated circuit device assembly that may include a microelectronic assembly in accordance with at least one embodiment of this disclosure.

FIG. 11 is a block diagram of an example electrical device that may include a microelectronic assembly, in accordance with any of the embodiments disclosed herein.

### DETAILED DESCRIPTION

Silicon photonics have emerged as replacements for various traditional LiDAR components, such as a gold box's complex free space optical system made of many discrete optical components, with a chip scale solution on a Silicon platform. EICs like trans impedance amplifiers (TIA), laser driver, optical switch drivers, semiconductor optical amplifiers (SOA) drivers, radio frequency (RF) modulator may be an integrated part of the silicon photonic systems. EIC to PIC communication may be a design factor that may impact signal integrity and system performance. As disclosed herein, a high channel density architecture may be used to allow EICs to communicate to PICs via flip chip interconnect to boost system performance.

As disclosed herein, instead of using longer interconnects, like wire-bond, the systems and methods disclosed herein may utilize flip chip technology to attach high density TIA silicon directly onto PICs. The pitch between each bump/interconnect on the TIA may be as low as 110 μm thus enabling high signal density per TIA. Flip chip interconnects (˜50 μm tall) may also be an order of magnitude shorter than typical wire bond interconnects thus providing much lower cross talk risk and a better RF interference (RFI) immunity solution. An additional instantiation of embodiments disclosed herein may include a flip chip attachment of a TIA on a substrate instead of the PIC.

Consistent with embodiments disclosed herein, flip chip TIA may be attached to the PIC or substrate to allow the assembly of higher channel count PICs within the same LIDAR form factor (FF) at equivalent cost to the current technology. Thus, the embodiments disclosed herein may enable higher performance LIDAR at the same cost and FF as prior generation solutions.

The TIA flip chip attached on a PIC may additionally provide a scalable solution with an increase in channel count of the PIC that can be supported by adding more higher channel count TIA parts without impact to the FF. In addition, additional passive silicon dies may be flip chipped on some or all power dissipating locations of the PIC, thus providing a low cost heat dissipation path through the top of the TIA and passive die as needed.

The TIA flip chip on PIC configurations disclosed herein may also provide a reliable interconnect joint between the PIC and the TIA due to the coefficient of thermal expansion (CTE) matched Si to Si interconnect. The configurations disclosed herein may allow for the absences of wire bonds in a top view of the PIC and TIA interconnect joints with the use of flip chip bumps in a sideview of the flip chip assembly.

The above discussion is intended to provide an overview of subject matter of the present patent application. It is not intended to provide an exclusive or exhaustive explanation. The description below is included to provide further information.

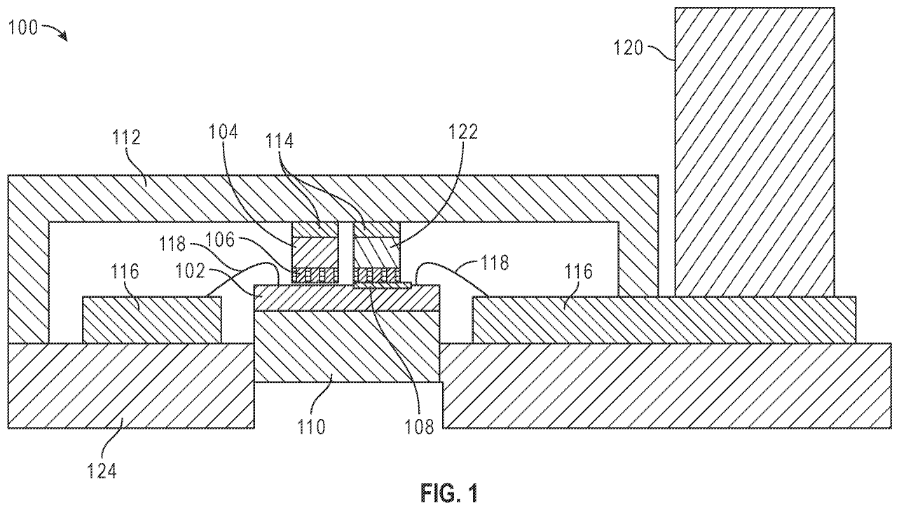

Turning now to the figures, FIG. 1 shows a light detection and ranging (LIDAR, or LiDAR) system 100 in accordance with at least one embodiment of this disclosure. System 100 may include a photonic integrated circuit (PIC) 102 that may communicate with a transimpedance amplifier (TIA) 104 or other electrical integrated circuit (EIC) devices that may drive optical elements or monitor their lifetimes. The signal integrity and communication channel density between the PICS and the EICs may be crucial for overall system performance. Flip chip technology, in which TIA 104 (or other EIC devices) may be directly attached to PIC 102 through copper pillars (with solder halls) bumps on TIA 104 (or other EIC devices) to a copper stud plated on the PIC 102, can increase the channel density as disclosed herein with the same die area and, hence, boost the overall performance.

As disclosed herein, system 100 may sometimes be referred to as a LIDAR gold box. As used herein, “gold box” refers to a packaging of multiple components together in one box. A gold box packaging may refer to a box that is hermetically sealed with components that may be precisely positioned. Consistent with embodiments disclosed herein, the box may not be hermetically sealed or some or all of the components may not be precisely positioned inside. The process for flip chip assembly may be referred to as a chip on wafer (CoW) die attach process. In one embodiment, the CoW process may begin with adding under bump metallurgy (UBM) to the PIC die wafer. Placement of EIC die 104 on PIC die 102 at a location on the PIC wafer may occur after dipping the EIC die bumps with solder in a flux tray. Reflow at 230-260° C. to form chip joint may be performed followed by underfill dispense and cure processes. Testing and singulation of PIC 102 with EIC 104 attached via stealth or laser dicing may also be performed. Still consistent with embodiments disclosed herein, other techniques may be used during fabrication of a gold box. For example, PIC 102 and EIC 104 may be embodied as silicon. As a result, matching the coefficients of thermal expansion between PIC 102 and EIC 104 may increase the reliability of the interconnect joint.

The CoW die attach process may form an interconnect 106 between each EIC 104 and PIC 102. Interconnect 106 may be used to transfer data through one or more analog and/or digital channels. As disclosed herein, interconnector 106 may transfer current-based signals. Signals transferred using interconnect 106 may include laser driving current, photodiode current, and/or the like. PIC 102 may have one or more EICs 104 attached to it, and/or EIC 104 may have one or more PICs 102 attached to it.

The pitch between each bump/interconnect on EIC 104 may be as low as 110 micrometers, thus enabling high signal density. Flip chip interconnects, with a length of, e.g., approximately 50 micrometers, may be an order of magnitude shorter than typical wire bond interconnects, thus providing lower cross talk risk and better radio frequency interference resistance.

System 100 may include a base 124 and a lid 112. Each of base 124 and/or lid 112 may be made of any suitable material, such as invar, aluminum, copper, iron, steel, gold, etc. System 100 may include a substrate 116. Substrate 116 may include any suitable component, such as interconnects. Substrate 116 may be any suitable material, such as silicon or organic resin. Substrate 116 may be connected to PIC 102 and/or EIC 104 through one or more wire bonds 118. Substrate 116 may also connect to a connector 120. Connector 120 may include one or more of any suitable electrical and/or optical connectors to provide a path for signals into or out of system 100, such as, but not limited to, power and/or data signals. A pitch between the paths may be less than 125 micrometers. Individual paths of the paths may be less than 100 micrometers long. An insert 110, such as an aluminum nitride insert, may be positioned below PIC 102 as shown in FIG. 1.

PIC 102 may include active devices like one or more semiconductor optical amplifiers (SOAs), monitor photodiodes (MPDs), photodetectors (PDs), etc. The area with those components may be referred to as the indium phosphide (InP) pool region 108. A heat spreader die (HSD) 122 may be attached to the area of PIC 102 above pool region 108. HSD die 122 may provide a pathway to remove heat from pool region 108 of PIC 102 via conduction heat transfer. HSD die 122 may be embodied as a passive silicon die that can be flip chipped on certain power dissipating locations on PIC 102 thus, providing a low-cost heat dissipation path through HSD die 122.

Pool region 108 may be sensitive to mechanical stress. For at least this reason, there may not be any underfill under HSD 122. Pool region 108 may utilize thermal management to remove heat out from pool region 108 as disclosed herein. Copper pillars, such as interconnects 106, connecting HSD 122 to PIC 102 may provide a pathway for conducting away the heat from pool region 108 to HSD 122, which may then act as a heat spreader to transfer the heat to lid 112. A thermal interface material (TIM) 114 may be located in between lid 112 and HSD 122 to improve the heat transfer efficiency.

PIC 102 may include both active and passive optical elements, such as, for example, a laser on the chip itself. For example, system 100 may use a frequency modulated continuous wave (FMCW) laser, which may provide high resolution and long-range compared to other LIDAR solutions. Consistent with embodiments disclosed herein, other lasers or laser modulation techniques may be used.

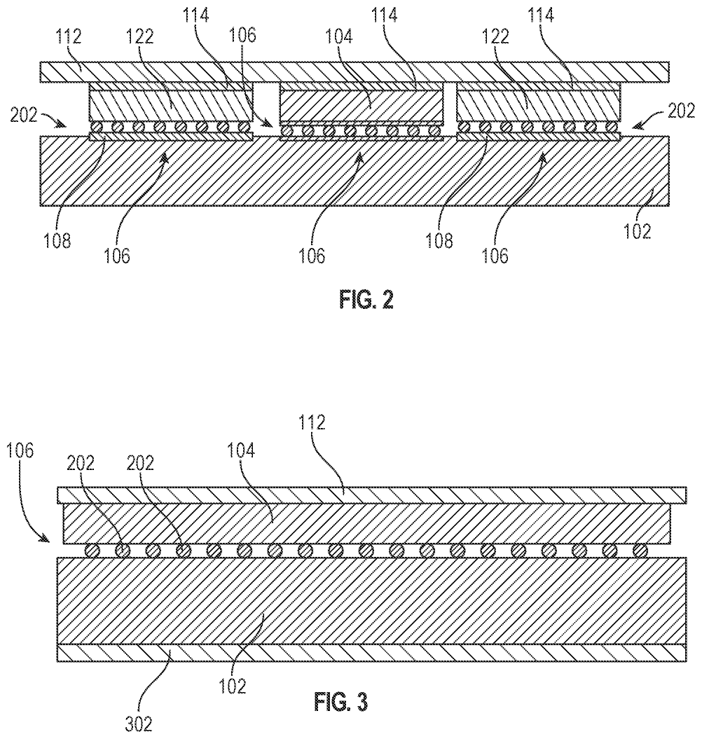

FIG. 2 shows a detail of the interconnection of one EIC 104 and two HSDs 122 connected to a PIC 102 consistent with embodiments disclosed herein. As shown in FIG. 2, interconnects 106 may include pillars 202. Pillars 202 may be copper pillars with solder. Pillars 202 may be connected to pool region 108. Pool region 108 may be bonded to PIC 102.

FIG. 3 shows a detail of interconnect 106 of EIC 104 connected to a PIC 102 consistent with embodiments disclosed herein. As shown in FIG. 3, PIC 102 may be connected to a substrate 302. Interconnect 106 may include pillars 202. PIC 102, pillars 202, and EIC 104 may be protected from the environment by lid 112. Lid 112 may be attached to base 124 shown in FIG. 1.

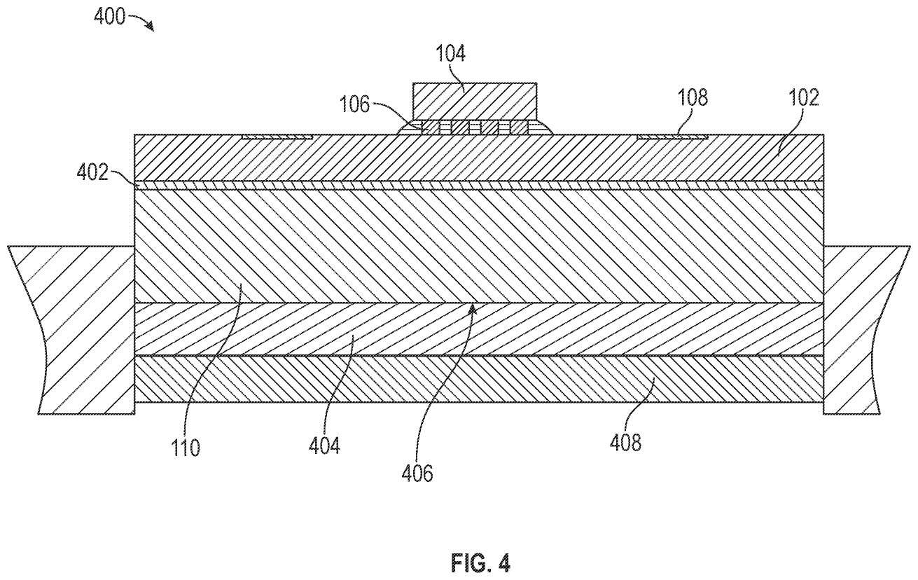

FIG. 4 shows a system 400, which may be an embodiment of system 100, with EIC 104 connected to PIC 102. FIG. 4 shows the heat dissipation path of PIC 102. Consistent with embodiments disclosed herein, the power of EIC 104 (which may be a TIA) may be, for example 3 W with a die area of, for example 32 mm². The TIA junction may have a maximum temperature, such as 67° C. A first thermal interface material (TIM) layer 402 may be located in between PIC 102 and insert 110, which may be an aluminum nitride insert. A second TIM layer 404 may be located on a surface 406 of insert 110 opposite first TIM layer 402. As disclosed herein, a heat sink or cold plate 408 may be pressed against surface 406 of insert 110 with second TIM layer 404 located on it. Heat may be removed from PIC 102 and/or EIC 104 through lid 112 shown in FIG. 1 or through a heat sink or cold plate 408, or other component attached at second TIM layer 404.

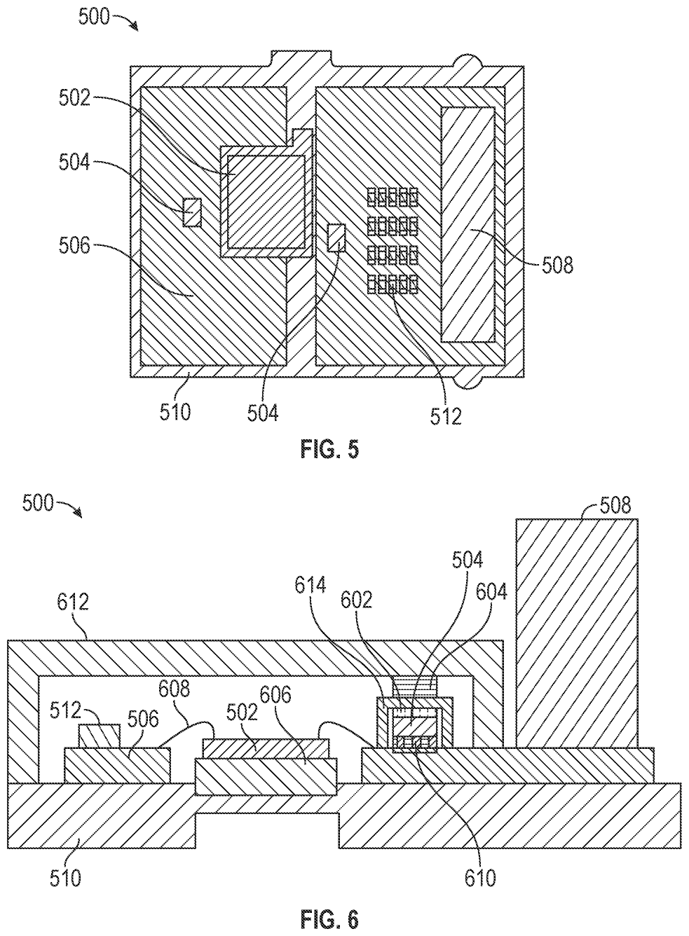

Referring now to FIGS. 5-7, embodiments disclosed herein may include system 500, sometimes referred to as a LIDAR “gold box,” which may include an EIC (e.g., TIA) die 504 that may be attached on a substrate 506. The process steps for creating such system 500 may include: 1) dispensing flux on solder balls of the substrate 506, 2) pick and place EIC die 504 die on substrate 506 and aligning EIC die 504 bumps to solder balls of substrate 506, 3) reflow at a temperature, such as 230-260° C., to form the solder joint, 4) high-temperature high-pressure water clean (i.e, deflux) to remove flux residue from an interconnect 610 (see FIG. 6), 5) fill the gap between EIC 504 and substrate 506 with epoxy (sometimes referred to as underfill) as a chip joint stress reduction mechanism to protect the chip joint integrity during assembly as well as for long term reliability of interconnect 610.

As disclosed herein, the heat dissipation path may be through the top of EIC die 504 as well as through the bottom via substrate 506. For top side heat dissipation, the thermal path may be provided through a first thermal interface material (TIM) layer 602 to an integrated heat spreader 614 and then through a second TIM layer 604 to lid 612, such as an Invar lid.

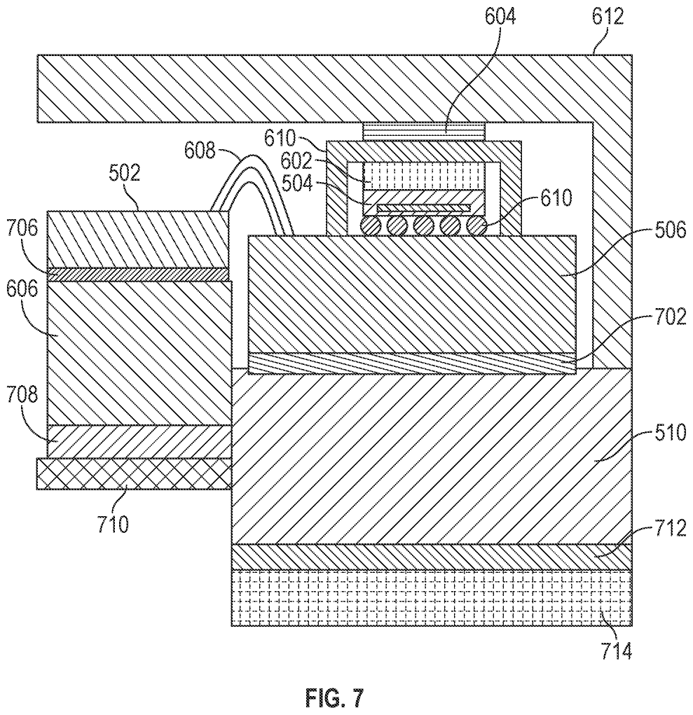

System 500 may include additional components such as a connector 508, a base 510, an aluminum nitride insert 606, one or more wire bonds 608, etc. Each of these components may be similar to corresponding component for system 100. System 500 may also include various other components 512. For example, components 512 may be various surface mount components. System 500 may include a first TIM layer 702 (see FIG. 7) located in between substrate 506 and base 510 and a second TIM layer 712 may be located in between base 510 and a cold plate (or other heat sink) 714. System 500 may include a first TIM layer 706 located in between PIC 502 and insert 606 and a second TIM layer 708 located in between insert 606 and a cold plate (or other heat sink) 710.

As disclosed herein, both system 100 and system 500 each provides a path for use of high channel count TIAs and reduce the interconnect length between the TIA and PIC. The choice of any of these TIA assembly options within a LIDAR “gold box” may allow for component design and selection flexibility for TIA, PIC, and substrate to improve the final product design for cost and performance. Using flip chip fabrication processes to attach the EIC to the PIC or substrate may allow the assembly of higher channel count PIC within the same LIDAR “gold box” form factor without increasing costs.

It should be appreciated that the embodiments of a LIDAR “gold box” described herein may have additional components or capabilities not explicitly described above. For example, additional electrical and/or optical components may be included. Optical input and output may be provided, such as an optical window, optical fibers, waveguides, etc. The various embodiments of a LIDAR “gold box” may be included in various systems, such as a LIDAR system, an autonomous vehicle, an autonomous robot, a drone, a ranging system, and/or any other suitable system. It should be appreciated that the techniques described herein are not limited to embodiments of a LIDAR “gold box.” Rather, the techniques may be applied to any suitable system, such as any suitable combination of EICs and PICs.

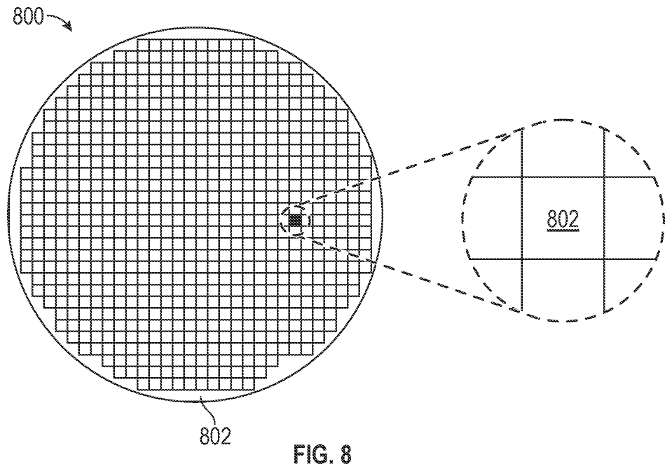

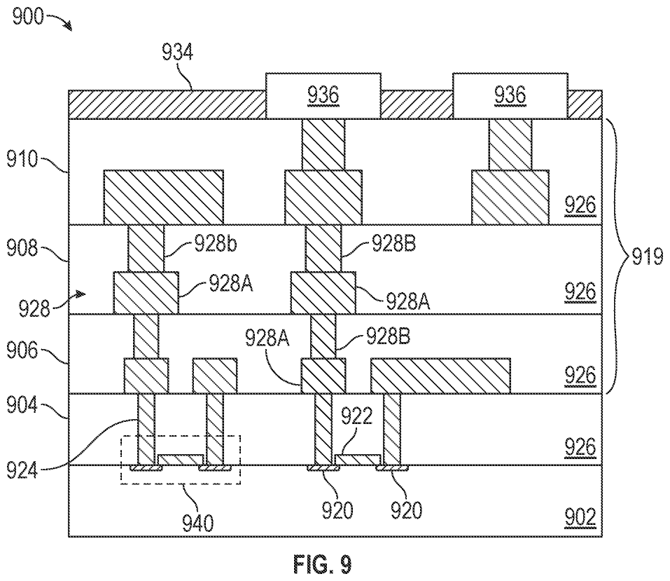

FIG. 8 is a top view of a wafer 800 and dies 802 that may be included in any of systems 100 or 500 or other systems disclosed herein (e.g., as any suitable ones of dies 102, 104, 502, 504). Wafer 800 may be composed of semiconductor material and may include one or more dies 802 having integrated circuit structures formed on a surface of wafer 800. The individual dies 802 may be a repeating unit of an integrated circuit product that includes any suitable integrated circuit. After the fabrication of the semiconductor product is complete, wafer 800 may undergo a singulation process in which dies 802 are separated from one another to provide discrete “chips” of the integrated circuit product. Die 802 may be any of dies 102, 104, 502, 504 disclosed herein. Die 802 may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, wafer 800 or die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processor unit (e.g., the processor unit 1110 of FIG. 11) or other logic that is configured to store information in the memory devices or execute instructions stored in the memory array. Various ones of systems 100 and 500 disclosed herein may be manufactured using a die-to-wafer assembly technique in which some dies 102, 104, 502, 504 are attached to wafer 800 that include others of dies 102, 104, 502, 504, and wafer 800 is subsequently singulated.

FIG. 9 is a cross-sectional side view of an integrated circuit device 900 that may be included in any of systems 100 and 500 disclosed herein (e.g., in any of dies 102, 104, 502, 504). One or more of integrated circuit devices 900 may be included in one or more dies 802 (see FIG. 8, for example). Integrated circuit device 900 may be formed on a die substrate 902 (e.g., wafer 800 of FIG. 8, for example) and may be included in a die (e.g., die 802 of FIG. 8, for example). Die substrate 902 may be a semiconductor substrate composed of semiconductor material systems including, for example, n-type or p-type materials systems (or a combination of both). Die substrate 902 may include, for example, a crystalline substrate formed using a bulk silicon or a silicon-on-insulator (SOI) substructure. In some embodiments, die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form die substrate 902. Although a few examples of materials from which die substrate 902 may be formed are described here, any material that may serve as a foundation for integrated circuit device 900 may be used. Die substrate 902 may be part of a singulated die (e.g., dies 802 of FIG. 8, for example) or a wafer (e.g., wafer 800 of FIG. 8, for example).

Integrated circuit device 900 may include one or more device layers 904 disposed on die substrate 902. Device layer 904 may include features of one or more transistors 940 (e.g., metal oxide semiconductor field-effect transistors (MOSFETs)) formed on die substrate 902. Transistors 940 may include, for example, one or more source and/or drain (S/D) regions 920, a gate 922 to control current flow between S/D regions 920, and one or more S/D contacts 924 to route electrical signals to/from S/D regions 920. Transistors 940 may include additional features not depicted for the sake of clarity, such as device isolation regions, gate contacts, and the like. Transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of transistor 940 along the source-channel-drain direction, the gate electrode may consist of a U-shaped structure that includes a bottom portion substantially parallel to the surface of die substrate 902 and two sidewall portions that are substantially perpendicular to the top surface of die substrate 902. In other embodiments, at least one of the metal layers that form the gate electrode may simply be a planar layer that is substantially parallel to the top surface of die substrate 902 and does not include sidewall portions substantially perpendicular to the top surface of die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

S/D regions 920 may be formed within die substrate 902 adjacent to gate 922 of individual transistors 940. S/D regions 920 may be formed using an implantation/diffusion process or an etching/deposition process, for example. In the former process, dopants such as boron, aluminum, antimony, phosphorous, or arsenic may be ion-implanted into die substrate 902 to form S/D regions 920. An annealing process that activates the dopants and causes them to diffuse farther into die substrate 902 may follow the ion-implantation process. In the latter process, die substrate 902 may first be etched to form recesses at the locations of S/D regions 920. An epitaxial deposition process may then be carried out to fill the recesses with material that is used to fabricate S/D regions 920. In some implementations, S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, S/D regions 920 may be formed using one or more alternate semiconductor materials such as germanium or a group material or alloy. In further embodiments, one or more layers of metal and/or metal alloys may be used to form S/D regions 920.

Electrical signals, such as power and/or input/output (I/O) signals, may be routed to and/or from the devices (e.g., transistors 940) of device layer 904 through one or more interconnect layers disposed on device layer 904 (illustrated in FIG. 9 as interconnect layers 906-910). For example, electrically conductive features of device layer 904 (e.g., gate 922 and S/D contacts 924) may be electrically coupled with interconnect structures 928 of interconnect layers 906-910. One or more interconnect layers 906-910 may form a metallization stack (also referred to as an “ILD stack”) 919 of integrated circuit device 900.

Interconnect structures 928 may be arranged within interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, interconnect structures 928 may include lines 928A and/or vias 928B filled with an electrically conductive material such as a metal. Lines 928A may be arranged to route electrical signals in a direction of a plane that is substantially parallel with a surface of die substrate 902 upon which device layer 904 is formed. For example, lines 928A may route electrical signals in a direction in and out of the page and/or in a direction across page. Vias 928B may be arranged to route electrical signals in a direction of a plane that is substantially perpendicular to the surface of die substrate 902 upon which device layer 904 is formed. In some embodiments, vias 928B may electrically couple lines 928A of different interconnect layers 906-910 together.

Interconnect layers 906-910 may include a dielectric material 926 disposed between interconnect structures 928, as shown in FIG. 9. In some embodiments, dielectric material 926 disposed between interconnect structures 928 in different ones of interconnect layers 906-910 may have different compositions; in other embodiments, the composition of dielectric material 926 between different interconnect layers 906-910 may be the same. Device layer 904 may include a dielectric material 926 disposed between transistors 940 and a bottom layer of the metallization stack as well. Dielectric material 926 included in device layer 904 may have a different composition than dielectric material 926 included in interconnect layers 906-910; in other embodiments, the composition of dielectric material 926 in device layer 904 may be the same as a dielectric material 926 included in any one of interconnect layers 906-910.

A first interconnect layer 906 (sometimes referred to as Metal 1 or “M1”) may be formed directly on the device layer 904. In some embodiments, first interconnect layer 906 may include lines 928A and/or vias 928B, as shown. Lines 928A of the first interconnect layer 906 may be coupled with contacts (e.g., S/D contacts 924) of device layer 904. Vias 928B of first interconnect layer 906 may be coupled with lines 928A of a second interconnect layer 908.

Second interconnect layer 908 (sometimes referred to as Metal 2 or “M2”) may be formed directly on first interconnect layer 906. In some embodiments, second interconnect layer 908 may include via 928B to couple lines 928 of second interconnect layer 908 with lines 928A of a third interconnect layer 910. Although lines 928A and vias 928B are structurally delineated with a line within individual interconnect layers for the sake of clarity, lines 928A and vias 928B may be structurally and/or materially contiguous (e.g., simultaneously filled during a dual-damascene process) in some embodiments.

Third interconnect layer 910 (sometimes referred to as Metal 3 or “M3”) (and additional interconnect layers, as desired) may be formed in succession on second interconnect layer 908 according to similar techniques and configurations described in connection with second interconnect layer 908 or first interconnect layer 906. In some embodiments, the interconnect layers that are “higher up” in metallization stack 919 in integrated circuit device 900 (i.e., farther away from device layer 904) may be thicker that the interconnect layers that are lower in metallization stack 919, with lines 928A and vias 928B in the higher interconnect layers being thicker than those in the lower interconnect layers,

Integrated circuit device 900 may include a solder resist or passivation material 934 (e.g., polyimide or similar material) and one or more conductive contacts 936 formed on interconnect layers 906-910. In FIG. 9, conductive contacts 936 are illustrated as taking the form of bond pads. Conductive contacts 936 may be electrically coupled with interconnect structures 928 and configured to route the electrical signals of transistor(s) 940 to external devices. For example, solder bonds may be formed on the one or more conductive contacts 936 to mechanically and/or electrically couple an integrated circuit die including integrated circuit device 900 with another component (e.g., a printed circuit board). Integrated circuit device 900 may include additional or alternate structures to route the electrical signals from interconnect layers 906-910. For example, conductive contacts 936 may include other analogous features (e.g., posts) that route the electrical signals to external components. Conductive contacts 936 may serve as part of or connect to interconnect as appropriate.

In some embodiments in which integrated circuit device 900 is a double-sided die, integrated circuit device 900 may include another metallization stack (not shown) on the opposite side of device layers 904. This metallization stack may include multiple interconnect layers as discussed above with reference to interconnect layers 906-910, to provide conductive pathways (e.g., including conductive lines and vias) between device layers 904 and additional conductive contacts (not shown) on the opposite side of integrated circuit device 900 from conductive contacts 936. These additional conductive contacts may serve as part of or connect to interconnect 106, 610, as appropriate.

In other embodiments in which integrated circuit device 900 is a double-sided die, integrated circuit device 900 may include one or more through silicon vias (TSVs) through die substrate 902; these TSVs may make contact with device layers 904, and may provide conductive pathways between the device layers 904 and additional conductive contacts (not shown) on the opposite side of integrated circuit device 900 from conductive contacts 936. These additional conductive contacts may serve as part of or connect to interconnects, as appropriate. Multiple integrated circuit devices 900 may be stacked with one or more TSVs in the individual stacked devices that can provide connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

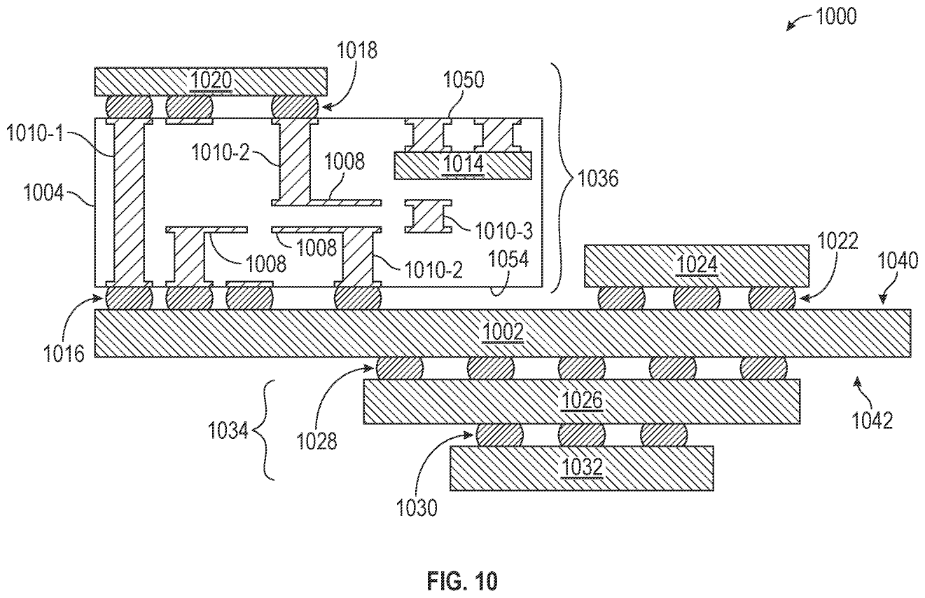

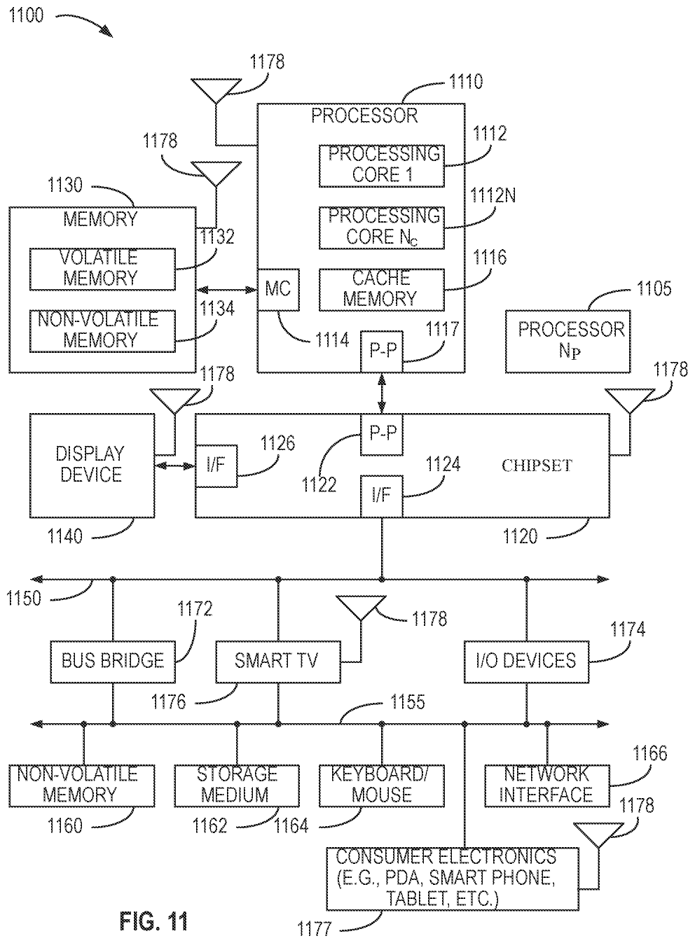

FIG. 10 is a cross-sectional side view of an integrated circuit device assembly 1000 that may include any of systems 100 and 500 disclosed herein. As disclosed herein, integrated circuit device assembly 1000 may be embodied in systems 100 and 500. Integrated circuit device assembly 1000 may include a number of components disposed on a circuit board 1002 (which may be a motherboard, system board, mainboard, etc.). Integrated circuit device assembly 1000 may include components disposed on a first face 1040 of circuit board 1002 and an opposing second face 1042 of circuit board 1002; generally, components may be disposed on one or both faces 1040 and 1042. Any of the integrated circuit components discussed herein with reference to the integrated circuit device assembly 1000 may take the form of any suitable ones of the embodiments of a LIDAR “gold box”, such as systems 100 and 500 disclosed herein.

In some embodiments, circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to circuit board 1002. In other embodiments, circuit board 1002 may be a non-PCB substrate. In some embodiments circuit board 1002 may be, for example, substrates 116 and 506. Integrated circuit device assembly 1000 illustrated in FIG. 10 includes a package-on-interposer structure 1036 coupled to first face 1040 of circuit board 1002 by coupling components 1016. Coupling components 1016 may electrically and mechanically couple the package-on-interposer structure 1036 to circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. Coupling components 1016 may serve as the coupling components illustrated or described for any of the substrate assembly or substrate assembly components described herein, as appropriate.

Package-on-interposer structure 1036 may include an integrated circuit component 1020 coupled to an interposer 1004 by coupling components 1018. Coupling components 1018 may take any suitable form for the application, such as the forms discussed above with reference to coupling components 1016. Although a single integrated circuit component 1020 is shown in FIG. 10, multiple integrated circuit components may be coupled to interposer 1004; indeed, additional interposers may be coupled to interposer 1004. Interposer 1004 may provide an intervening substrate used to bridge circuit board 1002 and the integrated circuit component 1020.

Integrated circuit component 1020 may be a packaged or unpackaged integrated circuit product that includes one or more integrated circuit dies (e.g., die 802 of FIG. 8, the integrated circuit device 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1020, a single monolithic integrated circuit die comprises solder bumps attached to contacts on the die. The solder bumps allow the die to be directly attached to the interposer 1004. Integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where integrated circuit component 1020 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets.” In embodiments where an integrated circuit component comprises multiple integrated circuit dies, interconnections between dies can be provided by the package substrate, one or more silicon interposers, one or more silicon bridges embedded in the package substrate (such as INTEL® embedded multi-die interconnect bridges (EMIBs)), or combinations thereof.

Generally, interposer 1004 may spread connections to a wider pitch or reroute a connection to a different connection. For example, interposer 1004 may couple the integrated circuit component 1020 to a set of ball grid array (BGA) conductive contacts of coupling components 1016 for coupling to circuit board 1002. In the embodiment illustrated in FIG. 10, integrated circuit component 1020 and circuit board 1002 are attached to opposing sides of interposer 1004. In other embodiments, integrated circuit component 1020 and circuit board 1002 may be attached to a same side of interposer 1004. In some embodiments, three or more components may be interconnected by way of interposer 1004.

In some embodiments, interposer 1004 may be formed as a PCB, including multiple metal layers separated from one another by layers of dielectric material and interconnected by electrically conductive vias. In embodiments where the interposer is a non-printed circuit board, interposer 1004 may be formed of an epoxy resin, a fiberglass-reinforced epoxy resin, an epoxy resin with inorganic fillers, a ceramic material, or a polymer material such as polyimide. In some embodiments, interposer 1004 may be formed of alternate rigid or flexible materials that may include the same materials described above for use in a semiconductor substrate, such as silicon, germanium, and other group III-V and group IV materials. Interposer 1004 may include metal interconnects 1008 and vias 1010, including but not limited to through hole vias 1010-1 (that extend from a first face 1050 of interposer 1004 to a second face 1054 of interposer 1004), blind vias 1010-2 (that extend from the first or second faces 1050 or 1054 of interposer 1004 to an internal metal layer), and buried vias 1010-3 (that connect internal metal layers).

In some embodiments, interposer 1004 can comprise a silicon interposer. Through silicon vias (TSV) extending through the silicon interposer can connect connections on a first face of a silicon interposer to an opposing second face of the silicon interposer. In some embodiments, interposer 1004 comprising a silicon interposer can further comprise one or more routing layers to route connections on a first face of interposer 1004 to an opposing second face of interposer 1004.

Interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on interposer 1004. Package-on-interposer structure 1036 may take the form of any of the package-on-interposer structures known in the art.

Integrated circuit device assembly 1000 may include an integrated circuit component 1024 coupled to first face 1040 of circuit board 1002 by coupling components 1022. Coupling components 1022 may take the form of any of the embodiments discussed above with reference to coupling components 1016, and integrated circuit component 1024 may take the form of any of the embodiments discussed above with reference to integrated circuit component 1020.

Integrated circuit device assembly 1000 illustrated in FIG. 10 includes a package-on-package structure 1034 coupled to second face 1042 of circuit board 1002 by coupling components 1028. Package-on-package structure 1034 may include an integrated circuit component 1026 and an integrated circuit component 1032 coupled together by coupling components 1030 such that the integrated circuit component 1026 is disposed between circuit board 1002 and integrated circuit component 1032. Coupling components 1028 and 1030 may take the form of any of the embodiments of coupling components 1016 discussed above, and integrated circuit components 1026 and 1032 may take the form of any of the embodiments of integrated circuit component 1020 discussed above. Package-on-package structure 1034 may be configured in accordance with any of the package-on-package structures known in the art.

FIG. 11 is a block diagram of an example electrical device 1100 that may include one or more of systems 100 and 500 disclosed herein. For example, any suitable ones of the components of electrical device 1100 may include one or more of the integrated circuit device assemblies 1000, integrated circuit components 1020, integrated circuit devices 900, or integrated circuit dies 802 disclosed herein, and may be arranged in any of systems 100 and, 500 disclosed herein.

In one embodiment, system 1100 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 1100 is a system on a chip (SOC) system.

In one embodiment, processor 1110 has one or more processing cores 1112 and 1112N, where 1112N represents the Nth processor core inside processor 1110 where N is a positive integer. In one embodiment, system 1100 includes multiple processors including 1110 and 1105, where processor 1105 has logic similar or identical to the logic of processor 1110. In some embodiments, processing core 1112 includes, but is not limited to, pre-fetch logic to fetch instructions, decode logic to decode the instructions, execution logic to execute instructions and the like. In some embodiments, processor 1110 has a cache memory 1116 to cache instructions and/or data for system 1100. Cache memory 1116 may be organized into a hierarchal structure including one or more levels of cache memory.

In some embodiments, processor 1110 includes a memory controller 1114, which is operable to perform functions that enable the processor 1110 to access and communicate with memory 1130 that includes a volatile memory 1132 and/or a non-volatile memory 1134. In some embodiments, processor 1110 is coupled with memory 1130 and chipset 1120. Processor 1110 may also be coupled to a wireless antenna 1178 to communicate with any device configured to transmit and/or receive wireless signals. In one embodiment, the wireless antenna interface 1178 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 1132 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 1134 includes, but is not limited to, flash memory, phase change memory (PCM), read-only memory (ROM), electrically erasable programmable read-only memory (EEPROM), or any other type of non-volatile memory device.

Memory 1130 stores information and instructions to be executed by processor 1110. In one embodiment, memory 1130 may also store temporary variables or other intermediate information while processor 1110 is executing instructions. In the illustrated embodiment, chipset 1120 connects with processor 1110 via Point-to-Point (PtP or P-P) interfaces 1117 and 1122. Chipset 1120 enables processor 1110 to connect to other elements in system 1100. In some embodiments of the invention, interfaces 1117 and 1122 operate in accordance with a PtP communication protocol such as the INTEL® QuickPath Interconnect (QPI) or the like. In other embodiments, a different interconnect may be used.

In some embodiments, chipset 1120 is operable to communicate with processor 1110, 1105N, display device 1140, and other devices 1172, 1176, 1174, 1160, 1162, 1164, 1166, 1177, etc. Chipset 1120 may also be coupled to a wireless antenna 1178 to communicate with any device configured to transmit and/or receive wireless signals.

Chipset 1120 connects to display device 1140 via interface 1126. Display 1140 may be, for example, a liquid crystal display (LCD), a plasma display, cathode ray tube (CRT) display, or any other form of visual display device. In some embodiments of the invention, processor 1110 and chipset 1120 are merged into a single SOC. In addition, chipset 1120 connects to one or more buses 1150 and 1155 that interconnect various elements 1174, 1160, 1162, 1164, and 1166. Buses 1150 and 1155 may be interconnected together via a bus bridge 1172. In one embodiment, chipset 1120 couples with a non-volatile memory 1160, a mass storage device(s) 1162, a keyboard/mouse 1164, and a network interface 1166 via interface 1124, smart TV 1176, consumer electronics 1177, etc.

In one embodiment, mass storage device 1162 includes, but is not limited to, a solid state drive, a hard disk drive, a universal serial bus flash memory drive, or any other form of computer data storage medium. In one embodiment, network interface 1166 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 11 are depicted as separate blocks within the system 1100, the functions performed by some of these blocks may be integrated within a single semiconductor circuit or may be implemented using two or more separate integrated circuits. For example, although cache memory 1116 is depicted as a separate block within processor 1110, cache memory 1116 (or selected aspects of 1116) can be incorporated into processor core 1112.

### Additional Notes

The following, non-limiting examples, detail certain aspects of the present subject matter to solve the challenges and provide the benefits discussed herein, among others.

Example 1 is a microelectronics package comprising: a photonic integrated circuit (PIC); an electrical integrated circuit (EIC); and an interconnect connecting the EIC to the PIC, the interconnect comprising a plurality of paths between the EIC and the PIC, wherein individual paths of the plurality of paths are less than 100 micrometers long.

In Example 2, the subject matter of Example 1 optionally includes wherein the EIC comprises a transimpedance amplifier.

In Example 3, the subject matter of Example 2 optionally includes wherein the PIC comprises a photodiode, wherein an output of the photodiode is connected to the transimpedance amplifier through a path of the plurality of paths of the interconnect.

In Example 4, the subject matter of any one or more of Examples 1-3 optionally include wherein a pitch between the plurality of paths is less than 125 micrometers.

In Example 5, the subject matter of any one or more of Examples 1-4 optionally include a box, wherein the box comprises a base and a lid, the PIC, EIC, and interconnect are positioned inside the box, and the EIC is thermally coupled to the lid through a thermal interface material layer.

In Example 6, the subject matter of Example 5 optionally includes a passive die comprising silicon positioned near a region of the PIC dissipating a higher amount of energy compared to nearby regions of the PIC, wherein the passive die is thermally coupled to the lid through a thermal interface material layer.

In Example 7, the subject matter of any one or more of Examples 5-6 optionally include wherein the apparatus is a light detection and ranging (LIDAR) gold box.

In Example 8, the subject matter of any one or more of Examples 1-7 optionally include wherein the PIC comprises at least one of a laser, a semiconductor optical amplifier, and a photodiode.

In Example 9, the subject matter of any one or more of Examples 1-8 optionally include wherein the microelectronics package is a component of a light detection and ranging (LIDAR) system.

In Example 10, the subject matter of any one or more of Examples 1-9 optionally include wherein the microelectronics package is a component of an electronics system further comprising: a processor in electrical communication with the PIC and the EIC; and a memory in electrical communication with the processor.

In Example 11, the subject matter of any one or more of Examples 1-10 optionally include an autonomous vehicle, the microelectronics package being a component of a navigation system of the autonomous vehicle.

Example 12 is a microelectronics package comprising: a substrate; a photonic integrated circuit (PIC) connected to the substrate via one or more wire bonds; an electrical integrated circuit (EIC); and an interconnect connecting the EIC to the substrate, the interconnect comprising a plurality of paths between the EIC and the substrate, wherein individual paths of the plurality of paths are less than 100 micrometers long.

In Example 13, the subject matter of Example 12 optionally includes wherein the EIC comprises a transimpedance amplifier.

In Example 14, the subject matter of Example 13 optionally includes wherein the PIC comprises a photodiode, wherein an output of the photodiode is connected to the transimpedance amplifier through a path of the plurality of paths of the interconnect.

In Example 15, the subject matter of any one or more of Examples 12-14 optionally include wherein a pitch between the plurality of paths is less than 125 micrometers.

In Example 16, the subject matter of any one or more of Examples 12-15 optionally include a box, wherein the box comprises a base and a lid, the PIC, EIC, substrate, and interconnect are positioned inside the box.

In Example 17, the subject matter of Example 16 optionally includes an integrated heat spreader, wherein the EIC is thermally coupled to the integrated heat spreader through a thermal interface material layer, and the integrated heat spreader is thermally coupled to the lid through a thermal interface material layer.

In Example 18, the subject matter of any one or more of Examples 16-17 optionally include wherein the microelectronics package is a component of a light detection and ranging (LIDAR) system.

In Example 19, the subject matter of any one or more of Examples 12-18 optionally include wherein the PIC comprises at least one of a laser, a semiconductor optical amplifier, and a photodiode.

In Example 20, the subject matter of any one or more of Examples 12-19 optionally include wherein the microelectronics package is a component of an electronics system further comprising: a processor in electrical communication with the PIC and the EIC; and a memory in electrical communication with the processor.

In Example 21, the subject matter of any one or more of Examples 12-20 optionally include an autonomous vehicle, the microelectronics package being a component of a navigation system of the autonomous vehicle.

Example 22 is a method comprising: depositing under bump metallurgy to a photonic integrated circuit (PIC) die wafer; depositing solder onto die bumps of an electrical integrated circuit (EIC); attaching the EIC die on the PIC die wafer; and performing a solder reflow to form an interconnect between the EIC die and the PIC die wafer.

In Example 23, the subject matter of Example 22 optionally includes underfilling between the EIC die and the PIC die wafer.

In Example 24, the subject matter of any one or more of Examples 22-23 optionally include wherein depositing the solder onto the die bumps of the EIC comprises depositing the solder onto the die bumps of a transimpedance amplifier.

In Example 25, the subject matter of any one or more of Examples 22-24 optionally include wherein depositing the under bump metallurgy to the PIC die wafer comprises depositing the under bump metallurgy to a photodiode, the method further comprising connecting a transimpedance amplifier to a path of the interconnect.

In Example 26, the subject matter of any one or more of Examples 22-25 optionally include forming a plurality of paths to form the interconnect, wherein a pitch between the plurality of paths is less than 125 micrometers.

In Example 27, the subject matter of any one or more of Examples 22-26 optionally include selecting at least one of a laser, a semiconductor optical amplifier, and a photodiode as the PIC.

In Example 28, the subject matter of any one or more of Examples 22-27 optionally include positioning the PIC die and the EIC die in a light detection and ranging (LIDAR) system.

Example 29 is a method comprising: dispensing flux on solder balls of a substrate; attaching an electrical integrated circuit (EIC) die to the substrate; forming an interconnect between the EIC die and the substrate via a solder reflow process; and wire bonding the substrate to a photonic integrated circuit (PIC).

In Example 30, the subject matter of Example 30 optionally includes underfilling between the EIC die and the substrate.

In Example 31, the subject matter of any one or more of Examples 29-30 optionally include wherein attaching the EIC to the substrate comprises attaching a transimpedance amplifier to the substrate.

In Example 32, the subject matter of any one or more of Examples 29-31 optionally include wherein wire bonding the PIC to the substrate comprises wire bonding a photodiode to the substrate, the method further comprising connecting an output of the PIC to the EIC through a path of the interconnect.

In Example 33, the subject matter of any one or more of Examples 29-32 optionally include forming a plurality of paths between the EIC and the PIC, wherein a pitch between the plurality of paths is less than 125 micrometers.

In Example 34, the subject matter of any one or more of Examples 29-33 optionally include wherein wire bonding the substrate to the PIC comprises wire bonding at least one of a laser, a semiconductor optical amplifier, and a photodiode to the substrate.

In Example 35, the subject matter of any one or more of Examples 29-34 optionally include positioning the PIC die, the EIC die, and the substrate in a light detection and ranging (LIDAR) system.

In Example 36, the microelectronics packages, systems, apparatuses, or method of any one or any combination of Examples 1-35 can optionally be configured such that all elements or options recited are available to use or select from.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure, is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined. with reference to the appended claims, along with the full scope of equivalents to which such claims are entitled.

What is claimed is:

1. A microelectronics package comprising:
a photonic integrated circuit (PIC);
an electrical integrated circuit (EIC); and
an interconnect connecting the EIC to the PIC, the interconnect comprising a plurality of paths between the EIC and the PIC, wherein individual paths of the plurality of paths are less than 100 micrometers long.

2. The microelectronics package of claim 1, wherein the EIC comprises a transimpedance amplifier.

3. The microelectronics package of claim 2, wherein the PIC comprises a photodiode, wherein an output of the photodiode is connected to the transimpedance amplifier through a path of the plurality of paths of the interconnect.

4. The microelectronics package of claim 1, wherein a pitch between the plurality of paths is less than 125 micrometers.

5. The microelectronics package of claim 1, further comprising a box, wherein
the box comprises a base and a lid,
the PIC, EIC, and interconnect are positioned inside the box, and
the EIC is thermally coupled to the lid through a thermal interface material layer.

6. The microelectronics package of claim 5, further comprising a passive die comprising silicon positioned near a region of the PIC dissipating a higher amount of energy compared to nearby regions of the PIC, wherein the passive die is thermally coupled to the lid through a thermal interface material layer.

7. The microelectronics package of claim 5, wherein the apparatus is a light detection and ranging (LIDAR) gold box.

8. The microelectronics package of claim 1, wherein the PIC comprises at least one of a laser, a semiconductor optical amplifier, and a photodiode.

9. The microelectronics package of claim 1, wherein the microelectronics package is a component of a light detection and ranging (LIDAR) system.

10. The microelectronics package of claim 1, further comprising an autonomous vehicle, the microelectronics package being a component of a navigation system of the autonomous vehicle.

11. A microelectronics package comprising:
a substrate;
a photonic integrated circuit (PIC) connected to the substrate via one or more wire bonds;
an electrical integrated circuit (EIC); and
an interconnect connecting the EIC to the substrate, the interconnect comprising a plurality of paths between the EIC and the substrate,
wherein individual paths of the plurality of paths are less than 100 micrometers long.

12. The microelectronics package of claim 11, wherein the EIC comprises a transimpedance amplifier.

13. The microelectronics package of claim 12, wherein the PIC comprises a photodiode, wherein an output of the photodiode is connected to the transimpedance amplifier through a path of the plurality of paths of the interconnect.

14. The microelectronics package of claim 11, wherein a pitch between the plurality of paths is less than 125 micrometers.

15. The microelectronics package of claim 11, further comprising an integrated heat spreader, wherein
the EIC is thermally coupled to the integrated heat spreader through a thermal interface material layer, and
the integrated heat spreader is thermally coupled to the lid through a thermal interface material layer.

16. The microelectronics package of claim 11, wherein the microelectronics package is a component of a light detection and ranging (LIDAR) system.

17. The microelectronics package of claim 11, wherein the PIC comprises at least one of a laser, a semiconductor optical amplifier, and a photodiode.

18. A method comprising:
depositing under bump metallurgy to a photonic integrated circuit (PIC) die wafer;
depositing solder onto die bumps of an electrical integrated circuit (EIC);
attaching the EIC die on the PIC die wafer; and
performing a solder reflow to form an interconnect between the EIC die and the PIC die wafer.

19. The method of claim 18, further comprising underfilling between the EIC die and the PIC die wafer.

20. The method of claim 18, wherein depositing the solder onto the die bumps of the EIC comprises depositing the solder onto the die bumps of a transimpedance amplifier.

21. The method of claim 18, wherein depositing the under bump metallurgy to the PIC die wafer comprises depositing the under bump metallurgy to a photodiode, the method further comprising connecting a transimpedance amplifier to a path of the interconnect.

22. The method of claim 18, further comprising forming a plurality of paths to form the interconnect, wherein a pitch between the plurality of paths is less than 125 micrometers.

23. The method of claim 18, further comprising selecting at least one of a laser, a semiconductor optical amplifier, and a photodiode as the PIC.

24. The method of claim 18, further comprising positioning the PIC die and the EIC die in a light detection and ranging (LIDAR) system.
